(19) United States
(12) Patent Application Publication
(10) Pub. No.: US 2013/0083415 A1
(43) Pub. Date: Apr. 4, 2013

(54) COLOR FILTER AND METHOD FOR MANUFACTURING THE SAME

(71) Applicant: BenQ Materials Corporation, Taoyuan County (TW)

(72) Inventors: Chen-Kuan KUO, New Taipei City (TW); Chien-Yi KAO, New Taipei City (TW); Lung-Hai WU, Taoyuan County (TW)

(73) Assignee: BENQ MATERIALS CORPORATION, Taoyuan County (TW)

(21) Appl. No.: 13/633,149

(22) Filed: Oct. 2, 2012

(30) Foreign Application Priority Data
Oct. 3, 2011 (TW) 100135774

(51) Int. Cl. B05D 5/06; H05K 13/00; B05D 3/02; G02B 5/22; B05D 3/12

(52) U.S. Cl. 359/885; 427/162; 427/510; 427/58

(57) ABSTRACT

A color filter and a method for manufacturing the same are provided. The method comprises the steps of providing a substrate having a color filter layer; forming an alignment material layer on the color filter layer; embossing the alignment material layer with an embossing means to transfer a microstructure from the surface structure of the embossing means onto the alignment material layer to form an alignment layer, wherein the alignment layer has a plurality of spacers and a plurality of alignment protrusions, and the height of each of the spacer is greater than the height of each of the alignment protrusion; and curing the alignment layer.

### RELATED APPLICATIONS

This application claims priority to Taiwan Application Serial Number 100135774, filed Oct. 3, 2011, which is herein incorporated by reference.

### BACKGROUND OF THE INVENTION

1. Field of the Invention

The invention relates to a color filter and a method for manufacturing the same.

2. Description of the Related Art

Liquid Crystal Display (LCD) has been a widely used display which has several advantages such as of small size, light weight, thin thickness and low power consumption. Therefore, the LCD is becoming one of the mainstream electronic products in the market.

The LCD mainly comprises a thin film transistor substrate, a color filter and a liquid crystal molecule layer between the two substrates. The liquid crystal molecule twists when the electric current passes through the thin film transistor substrate and varies the electric field. Therefore, the vibration direction of polarized light can be changed so as to determine the bright/dark level of pixels with a polarizer. The color filter correspondingly associated with the bright/dark level of pixels forms images of the LCD.

Under an exerted electric field, the liquid crystal molecules change orientations with various driving mode of the electric field and structures of the alignment layer. In view of the orientation way of the liquid crystal molecules, the LCD can be generally divided into being driven in Twisted Nematic (TN) mode, In-Plane Switching (IPS) mode and Multi-domain Vertical Alignment (MVA) mode.

There are photo spacers and an alignment layer on the color filter of the TN mode and IPS mode LCD. The alignment layer is applied to make the liquid crystal molecules parallel to the color filter in the condition of no exerted electric field. Normally, a photo resistance layer is formed on a color filter substrate, and photo spacers are then formed with optical lithography process. Next, an alignment layer is coated on the color filter substrate having photo spacers, and then the alignment layer is rubbed so as to form micro-grooves. However, the aforementioned processes are complex and non-economical for the use of materials of the photo resistance layer.

In the MVA mode LCD, there are also photo spacers and an alignment layer on the color filter. The alignment layer is applied to make the liquid crystal molecules and the color filter vertical with each other in the condition of no exerted electric field. Normally, a photo resistance layer is formed on a color filter substrate and photo spacers are then formed with optical lithography process. Subsequently, a protruding alignment layer is formed on the color filter substrate having photo spacers. The above-mentioned processes are complex too and time-consuming. Further, the structures of the alignment layer will usually deteriorate the transparence of panel. As a result, there still exists a need to provide a method for manufacturing a color filter so as to improve the above issues.

### SUMMARY OF THE INVENTION

In an embodiment of the present invention, a method for manufacturing a color filter comprises the steps of providing a substrate having a color filter layer; forming an alignment material layer on the color filter layer; embossing the alignment material layer with an embossing means to reproduce a microstructure from a surface of the embossing means onto the alignment material layer to form an alignment layer, wherein the alignment layer has a plurality of spacers and a plurality of alignment protrusions, and the height of each spacer is greater than the height of each alignment protrusion; and curing the alignment layer.

In another embodiment of the present invention, a color filter comprises a substrate having a color filter layer; a black matrix formed on the substrate to define a plurality of sub-pixels on the substrate, wherein the color filter layer covers each of the sub-pixels; and a transparent conductive layer formed on the color filter layer and the black matrix; and an alignment layer covering the transparent conductive layer, wherein the alignment layer comprises a plurality of spacers in contact with the transparent conductive layer above the black matrix; and a plurality of alignment protrusions in contact with the transparent conductive layer above the color filter layer, wherein the spacers and alignment protrusions are made of the alignment material layer.

The method of the present invention is to provide an alignment layer having spacers and alignment protrusions by embossing a layer of the alignment material and without using optical lithography process. Therefore, the disclosed method can simplify the manufacturing process of an alignment layer and save the manufacture cost thereof.

The above and other aspects of the invention will become better understood with regard to the following detailed description of the preferred but non-limiting embodiments). The following description is made with reference to the accompanying drawings.

### BRIEF DESCRIPTION OF THE DRAWINGS

FIG. 1A to 1B show cross-sectional views of each process step of a color filter of an embodiment of the present invention; and

FIG. 2 shows a top view of a color filter of an embodiment of the present invention.

### DETAILED DESCRIPTION OF THE INVENTION

Please note the drawings shown in the Figures are for illustrative purposes only and not to scale.

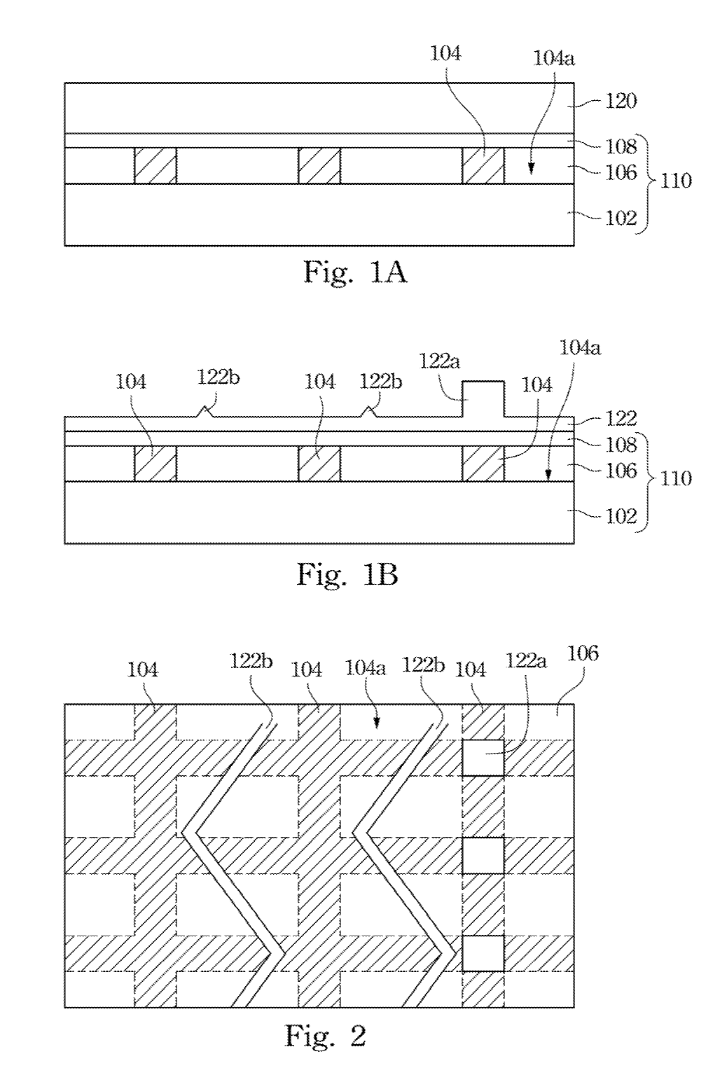

An embodiment of the present invention is provided to illustrate the method for manufacturing a color filter. Firstly, a color filter substrate 110 having a color filter layer 106 is provided as shown in FIG. 1A. In an embodiment of the present invention, the method for manufacturing the color filter substrate 110 comprises the steps of forming a black matrix 104 on a substrate 102 to define sub-pixels 104a; forming the color filter layer 106 to cover each of the sub-pixel; and forming a transparent conductive layer 108 to cover the color filter layer 106 and the black matrix 104.

The substrate 102 can be a glass, quartz or flexible plastic substrate. The materials of the black matrix 104 are made of metal and black resin. The black matrix 104 is manufactured by forming a masking material layer on the substrate 102 and photolithographing the masking material layer to form the black matrix 104 defining the sub-pixels 104a. The material of the color filter layer 106 contains dyeing resin. In step of forming the color filter layer 106, the color filter layer 106 can be formed on each of the sub-pixel 104a by photolithography or printing process. The material of the transparent conductive layer 108, for example, is ITO. The transparent conductive layer 108 can be produced by physical vapor deposition or chemical vapor deposition process.

Referring to FIG. 1, an alignment material layer 120 is formed on the color filter substrate 110 by, for example, a coating process. The material of the alignment material layer 120 is liquid or colloidal state. The material of the alignment material layer 120 is selected from the group consisting of photo-curing polyimide, thermo-curing polyimide and a combination or a precursor thereof. The material above mentioned can form solid state polyimide during irradiation with UV ray or heating process. The photo-curing polyimide or the precursor thereof comprise such as polyamic acid with carboxylic acid group or amide group and is cured during irradiation with UV ray after adding photo-initiator. The therm-curing polyimide or the precursor thereof is such as soluble polyimide or polyamic acid.

After forming alignment material layer 120, the alignment material layer 120 is engraved with an embossing means to transfer a microstructure from the surface structure of the embossing means onto the alignment material layer 120 to form an alignment layer 122 as shown in FIG. 1B, wherein the alignment layer 122 has a plurality of spacers 122a and a plurality of alignment protrusions 122b, and the height of each of the spacer 122a is greater than the height of each of the alignment protrusion 122b.

The top surface of the embossing means is patterned with concave and convex structures. The pattern of the concave and convex structures is to the arrangement of the structures of the plurality of spacers 122a and the plurality of alignment protrusions 122b. In an embodiment of the present invention, the locations of the concave structures of the embossing means correspond to the locations of the structures of the plurality of spacers 122a and the plurality of alignment protrusions 122b are in different depths of grooving structures. In another embodiment of the present invention, the embossing means is a roller with a patterned structure on the surface. Therefore, when the surface of the roller contacts the alignment material layer 120, the alignment material layer 120 reproduces a microstructure from the surface of the roller to form an alignment layer 122.

After the alignment material layer 120 is embossed, the alignment layer 122 is cured. The alignment layer 122 can be cured by irradiation with UV and heating. The processing time of a UV irradiation is shorter. In an embodiment, the cured spacers 122a are disposed between the Thin-Film-Transistor and the color filter in LCD to maintain the distance thereof and to control the thickness of liquid crystal layer. The height of each cured spacer 122a is in a range of 2 μm to 10 μm.

In an embodiment of the present invention, the cured alignment protrusions 122b formed by the disclosed method can be used in Multi-domain Vertical Alignment mode LCD. The height of the alignment protrusion 122b formed by the disclosed method is in a range of 0.1 μm to 1 μm. Because the height of the alignment protrusion 122b is lower than the height of the alignment protrusion made by photolithography process, the transparence of Multi-domain Vertical Alignment mode LCD will not decrease. The height ratio of the spacer 122a to the alignment protrusion 122b is in a range of 20 to 100.

In an embodiment of the present invention, the steps of forming the alignment material layer 120; embossing the alignment material layer 120 to form the alignment layer 122; and curing the alignment layer 122 can be implemented by roll-to-roll process. In an embodiment, the color filter substrate 110 is a flexible plastic substrate having the color filter layer 106. Then, the alignment material layer 120 is coated on the color filter substrate 110, and is embossed with a roller with a patterned structure on the surface to transfer a microstructure onto the alignment material layer 120 from the surface structure of the roller to form the alignment layer 122. Subsequently, the alignment layer 122 is cured by UV irradiation or thermal treatment. In the embodiment of the present invention, the manufacturing method does not need photolithography process, and can shorten the processing time and reduce cost.

In another embodiment of the present invention, a color filter as shown in FIG. 1B and FIG. 2 is provided. The color filter comprises a substrate 102; a black matrix 104 formed on the substrate 102 for defining a plurality of sub-pixels 104a on the substrate 102; a color filter layer 106 covering each of the sub-pixels 104a; a transparent conductive layer 108 formed on the color filter layer 106 and the black matrix 104; and an alignment layer 122 covering the transparent conductive layer 108, wherein the alignment layer 122 comprises a plurality of spacers 122a above the black matrix 104; and a plurality of alignment protrusions 122b above the color filter layer 106 wherein the spacers 122a and alignment protrusions 122b are made of the alignment layer 122. Because the plurality of spacers 122a is placed above the black matrix 104, the transparence of LCD does not decrease.

The substrate 102 is glass, quartz or flexible plastic substrate.

The materials of the black matrix 104 are metal and black resin.

The color filter layer 106 comprises red photo resist, green photo resist, blue photo resist or other color photo resist.

The material of the transparent conductive layer 108, for example, is ITO.

The material of the alignment layer 122, for example, is selected from the group consisting of photo-curing polyimide, thermo-curing polyimide and a combination thereof. The height of each spacer 122a is in a range of 2 μm to 10 μm. In an embodiment, the alignment protrusions 122b are applied for Multi-domain Vertical Alignment mode LCD. The height of each alignment protrusion 122b is in a range of 0.1 μm to 1 μm.

Referring to FIG. 2, the plurality of spacers is placed on the cross of the black matrix 104. The plurality of alignment protrusions 122b is placed on the black matrix 104 and color filter layer 106, and is presented in a zigzag line. Liquid crystal molecules are aligned with the zigzag lines with various directions to generate a wide view-angle effect.

Accordingly, a color filter and a method for manufacturing the same are provided, wherein the steps comprise embossing the alignment material layer to form an alignment layer with a plurality of spacers and a plurality of alignment protrusions: curing the alignment layer by irradiation with UV ray or heating. The manufacturing method does not need photolithography process, and can shorten the processing time and reduce cost. In addition, the height of the alignment protrusions is less than 1 μm, thereby the alignment protrusions do not decrease the transparence of panel, and on the contrary enhance the brightness of LCD.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for manufacturing a color filter, comprising the steps of:
providing a color filter substrate having a color filter layer;
forming an alignment material layer on the color filter layer;
embossing the alignment material layer with an embossing means to transfer a microstructure from a surface structure of the embossing means onto the alignment material layer to form an alignment layer, wherein the alignment layer has a plurality of spacers and a plurality of alignment protrusions, and the height of each of the spacer is greater than the height of each of the alignment protrusion; and
curing the alignment layer.

2. The method according to claim 1, wherein the material of the alignment material layer is selected from the group consisting of photo-curing polyimide, thermo-curing polyimide and a combination thereof.

3. The method according to claim 1, wherein the step of curing the alignment layer comprises irradiation of the alignment layer with UV ray.

4. The method according to claim 1, wherein the step of curing the alignment layer comprises heating the alignment layer.

5. The method according to claim 1, wherein the step of curing the alignment layer comprises curing the plurality of spacers and the plurality of alignment protrusions, wherein the height of the cured spacers is in a range of 2 to 10 μm, and the height of the cured alignment protrusions is in a range of 0.1 to 1 μm.

6. The method according to claim 5, wherein the height ratio of the cured spacers to the cured alignment protrusions is in a range of 20 to 100.

7. The method according to claim 1, wherein the substrate having the color filter layer comprises:
a black matrix formed on the substrate to define a plurality of sub-pixels on the substrate;
the color filter layer formed on and covering each of the sub-pixels; and
a transparent conductive layer formed on the color filter layer and the black matrix.

8. The method according to claim 1, wherein the embossing means is a roller with a patterned structure on the surface.

9. A color filter, comprising:
a substrate;
a black matrix formed on the substrate and defining a plurality of sub-pixels on the substrate;
a color filter layer covering each of the sub-pixels;
a transparent conductive layer formed on the color filter layer and the black matrix; and
an alignment layer covering the transparent conductive layer, wherein the alignment layer comprises:
a plurality of spacers in contact with the transparent conductive layer above the black matrix; and
a plurality of alignment protrusions in contact with the transparent conductive layer above the color filter layer, wherein the spacers and alignment protrusions are made of a material same as that of the alignment layer.

10. The color filter according to claim 9, wherein the height of the cured spacers is in a range of 2 to 10 μm, and the height of the cured alignment protrusions in a range of 0.1 to 1 μm.
